(19) United States
(12) Patent Application Publication
(10) Pub. No.: US 2025/0075762 A1
(43) Pub. Date: Mar. 6, 2025

(54) SENSORIZED BRAKING DEVICE FOR A VEHICLE, A PIEZOELECTRIC SHEAR FORCE DETECTING SENSOR, AND A SHEAR FORCE DETECTING METHOD

(71) Applicant: ITT Italia S.R.L., Lainate (Milano) (IT)

(72) Inventors: Marco Terranova, Torino (IT); Stefano Serra, Saluzzo (Cuneo) (IT); Gianmaria Milani, Candiolo (Torino) (IT); Cesare Zangari, Pinerolo (Torino) (IT)

(21) Appl. No.: 18/681,002

(22) PCT Filed: Jun. 13, 2022
(86) PCT No.: PCT/EP2022/066020

§ 371 Date: Feb. 2, 2024

(30) Foreign Application Priority Data
Aug. 3, 2021 (IT) 102021000021017

(51) Int. Cl. F16D 66/00; G01L 1/16

(52) U.S. Cl. CPC F16D 66/00; G01L 1/16; F16D 2066/005

(57) ABSTRACT

The sensorized braking device (1) for a vehicle, comprising at least one piezoelectric sensor (2) for measuring shear force, an electrical circuit (12) configured to collect signals from the sensor (2), wherein the sensor (2) comprises a piezoelectric material (3), a first and at least a second readout electrode (6, 7), wherein the piezoelectric material (3) comprises a first flat face (4) and a second flat face (5) facing the first flat face (4), the first and second flat faces (4, 5) extending in parallel planes identified by two orthogonal directions y and z, wherein the piezoelectric material (3) is polarized in the z direction, wherein the first electrode (6) is positioned on the first face (4) and the second electrode (7) is positioned on the second face (5) and has at least one extension (7a, 7b) on the first face (4) separated from the first electrode (6), and wherein the extension (7a. 7b) of the second electrode (7) is arranged symmetrically with respect to the y- and z-axes.

### FIELD

The following disclosure relates to a sensorized braking device for a vehicle, a piezoelectric shear force detecting sensor, and a shear force detecting method

### SUMMARY

Piezoelectricity is the property of certain materials to polarize, generating an accumulation of electrical charge, and therefore a difference in potential, when mechanically stressed. Similarly, it can have the opposite effect, i.e., to generate a deformation of a material, subjecting it to electrical voltage. This is called the inverse piezoelectric effect.

Piezoelectric materials include quartz crystal, tourmaline, and Rochelle salts. These exhibit a relatively small piezoelectric response to external movement not optimal for some applications such as the one in question, for example. To overcome this problem, certain polycrystalline ferroelectric ceramics such as barium titanate (BaTiO3) and lead zirconate titanate (PZT) are synthesized, such that the synthesized ceramics exhibit more pronounced piezoelectric properties i.e. higher electrical voltages at the same mechanical stress or larger displacements when electrically stressed.

To confer piezoelectric properties to the piezoceramic materials, these must undergo the polarization procedure.

For this purpose, a strong electric field of several kV/mm is applied to create an asymmetry in the ceramic compound which previously appears to have randomly oriented domains and therefore no net polarization. The application of an external electric field rearranges the dipoles of the material, which are aligned parallel to its direction, making the total electric dipole no longer zero. The material is consequently polarized.

After polarization, most of the reorientations are preserved, even without the application of an electric field until the material is brought to a temperature greater than the Curie Temperature (CT), characteristic of the material.

At temperatures below CT, the lattice structure of PZT crystallites may distort due to external mechanical stress, causing a change in global polarization. This is therefore a mechanism of interest for piezoelectric technology. At temperatures above CT, the piezoceramic material loses its asymmetry within the lattice, causing the loss of its piezoelectric properties.

After synthesization and polarization, the piezoceramic material presents as very hard and high density and can be sawed and machine-worked if necessary. The compacted materials come in different shapes like discs, bars, and cylinders. The last stage of the manufacturing process includes the placement of electrodes. The electrodes are applied to the piezoceramic material by screen printing or PVD (cathodic sputtering) technology and then baked. The thickness of the conductive material may vary from 1 μm to 10 μm depending on the final application of the sensor.

The way that the electrodes are geometrically arranged identifies 2 different types of sensors: one with the electrodes on 2 opposite faces, and one with both contacts on the same face of the piezoceramic. This last is called Wrapped Around Electrode (WAC) because one of the two electrodes wraps around a perimeter edge of the piezoelectric material to be placed on the same face as the other electrode.

Polarized piezoelectric materials are characterized by different coefficients and relationships.

To put it simply, the base relationships between the electrical and elastic properties can be represented as follows:

$$D = d \cdot T + {ε}^{T} \cdot E$$

$$S = {S}^{E} \cdot T + d \cdot E$$

where D is the electric flux density, T the mechanical stress, E the electric field, S the mechanical stress, d the piezoelectric charge coefficient, ET the permittivity, and SE the elasticity coefficient. These relationships apply to small electric and mechanical amplitudes, i.e., small signal values. In this range, the relationships between mechanical strain, elastic S or stress T, and electric field E or electric flux density D are linear, and the coefficient values are constant. As shown in FIG. 1, the directions are designated by 1, 2, and 3, corresponding to the X, Y, and Z axes of the classical right-hand orthogonal set of axes. The rotational axes are designated by 4, 5, and 6. The polarization direction (axis 3) is established during the polarization process by a strong electric field applied between the two electrodes.

A characteristic fundamental parameter of a piezoelectric material is that the coupling between the mechanical deformation in a certain direction j and the potential generated on the faces in direction i is governed by the coefficients dᵢⱼ, grouped in the d matrix:

Typically, piezoelectric sensors adopted in compressive or tractive force measurements are

$$d = ( \begin{matrix}{d}_{11} & {d}_{12} & {d}_{13} & {d}_{14} & {d}_{15} & {d}_{16} \\ {d}_{12} & {d}_{22} & {d}_{23} & {d}_{24} & {d}_{25} & {d}_{26} \\ {d}_{13} & {d}_{23} & {d}_{33} & {d}_{34} & {d}_{35} & {d}_{36} \\ {d}_{14} & {d}_{24} & {d}_{34} & {d}_{44} & {d}_{45} & {d}_{46} \\ {d}_{15} & {d}_{25} & {d}_{35} & {d}_{45} & {d}_{55} & {d}_{56} \\ {d}_{16} & {d}_{26} & {d}_{36} & {d}_{46} & {d}_{56} & {d}_{66}\end{matrix} )$$

polarized so that their polarization axis agrees with the direction of mechanical deformation to be measured (z-axis, 3), while charges are collected from the faces orthogonal to that direction (faces 3). The result is that the response to a compression of the sensor is regulated by the coefficient d₃₃.

With similar reasoning, we therefore deduce that the sensors used in shear stress measurements, i.e., where there is relative sliding between 2 opposing faces, are governed primarily by coefficient d₁₅ (1 surface orthogonal to the x-axis, 5 shear strain along z-axis, of polarization). When mechanical deformations are not perfectly unidirectional, the other coefficients can introduce a contribution to the final signal, at times also generating effects that are uncontrollable or destructive, as we will see later in the case of sensors with reported electrodes.

A sensorized braking device for a vehicle, particularly but not only an smart brake pad, is a braking device configured (e.g., with adequate architecture of the hardware and software system and some algorithms) to measure one or more parameters, such as the temperature of the brake pad and/or static and dynamic quantities, including normal forces and shear applied during braking.

A shear force detecting sensor may include a sheet of piezoelectric material with a main lying plane defined by orthogonal y and z directions, a thickness defined by an x direction orthogonal to the main lying plane yz, polarization according to the z direction, and configured to collect electrical charges on faces parallel to the main lying plane yz.

A limit of the peculiarities described above lies in the fact that, when used to read the shear force signal, the electrodes collect a significant amount of charges produced even in the normal direction which can to some degree complicate the correct interpretation of the signal. This phenomenon is called “crosstalk”.

“Crosstalk” consists of an electric signal generated by the shear force sensor when a force is applied only according to direction x.

“Crosstalk” is a phenomenon present in any piezoelectric component, but some types of piezoelectric shear sensors are affected by it more significantly, like the reported electrode sensors.

In particular, if the piezoelectric shear sensor is integrated into a braking device in which the shear force is always associated with a normal force during braking, “crosstalk” can make measurements unreliable and unrepeatable.

The reported electrode sensors on a sensorized brake pad is the optimal solution for achieving a large-scale production process, but are also the most sensitive to “crosstalk” if not correctly designed and produced.

If shear force sensors of this type are integrated into the two brake pads that make up a disc brake, the two shear force sensors will produce completely different readout signals because the “crosstalk” signal makes a variable contribution that can be concordant or discordant with the signal that would be generated by a pure shear force.

Industrially (high volumes and low costs) it is preferable to use the reported electrode sensor, but if not properly designed, this ends up being inappropriate for use in brake pads.

The technical task of this invention is to remedy the disadvantages of the known technology. Within the scope of this technical task, one purpose of the invention is to provide a shear force sensor and a sensorized braking device incorporating a shear force sensor that produces reliable and repeatable measurements when the shear force sensor is simultaneously subjected to a shear force and a normal force.

The other purpose of the invention is to provide a shear force sensor and a sensorized braking device incorporating a shear force sensor that is easily industrialized and produces reliable and repeatable measurements when the shear force sensor is subjected to both a shear force and a normal force simultaneously.

The technical task, as well as this and other purposes, are achieved according to the invention by a sensorized braking device for a vehicle, made up of:
at least one piezoelectric shear force sensor;
an electrical circuit configured to collect signals from at least one said sensor;
in which said sensor is made up of:
a piezoelectric material, a first and at least a second readout electrode, where said piezoelectric material includes a first flat face and a second flat face facing said first flat face, the first and second flat faces extending in parallel planes identified by two orthogonal directions y and z, where said piezoelectric material is polarized in said z direction, and where an electrical signal can be collected by said readout electrodes when said piezoelectric material is simultaneously subjected to a normal force in a direction x orthogonal to said two directions y and z and to said shear force in said z direction;
characterized by the fact that said first electrode is positioned on the first face and said second electrode is positioned on the second face and has at least one extension on the first face separated from said first electrode, and by the fact that at least one extension of said second electrode is arranged symmetrically with respect to said y and z axes.

In a preferred mode of implementation, the sensorized braking device for a vehicle includes a brake pad comprising a backing plate and a block of friction material, where said electrical circuit is interposed between said backing plate and said block of friction material and said at least one sensor is interposed between said electrical circuit and said block of friction material. This invention also contains a piezoelectric shear force sensor, made of a piezoelectric material, a first and at least a second readout electrode, where said piezoelectric material includes a first flat face and a second flat face facing said first flat face, the first and second flat faces extending in parallel planes identified by two orthogonal directions y and z, where said piezoelectric material is polarized in said z direction, and where an electrical signal can be collected by said readout electrodes when said piezoelectric material is simultaneously subjected to a normal force in a direction x orthogonal to said two directions y and z and to said shear force in said z direction;
characterized by the fact that said first electrode is positioned on the first face and said second electrode is positioned on the second face and has at least one extension on the first face separated from said first electrode, and by the fact that at least one extension of said second electrode is arranged symmetrically with respect to said y and z axes.

Also preferably, said first electrode is symmetrically placed with respect to said axes y and z.

This invention finally contains a method of shear force sensing with a sensorized braking device for a vehicle, comprising:
at least one piezoelectric shear force sensor;
an electrical circuit configured to collect signals from at least one said sensor;
in which said sensor is made up of:
a piezoelectric material, a first and at least a second readout electrode, where said piezoelectric material includes a first flat face and a second flat face facing said first flat face, said first and second flat faces extending in parallel planes identified by two orthogonal directions y and z, where said piezoelectric material is polarized in said z direction, where said first electrode is positioned on said first face and said second electrode is positioned on said second face, characterized by the fact of extending said second electrode on said first face with at least one extension separate from said first electrode, by the fact of arranging at least one extension of said second electrode symmetrically with respect to said y and z axes, and by the fact of collecting an electrical signal from said reading electrodes when said piezoelectric material is simultaneously subjected to a normal force in a direction x orthogonal to said two directions y and z and to said shear force in said z direction.

### BRIEF DESCRIPTION OF DRAWINGS

Various forms of implementation are portrayed in the drawings attached for illustrative purposes and must not in any way be interpreted as limitative of the scope of this disclosure. Various peculiarities of the different forms of implementation disclosed may be combined to create additional forms of implementation, which are part of this disclosure.

FIG. 1 schematically illustrates a system of orthogonal coordinates to describe the properties of a polarized piezoelectric material;

FIG. 2 schematically shows a shear force detecting sensorized braking device;

FIGS. 3a and 3b show schematically in axonometry and respectively in drawings a first mode of implementation of the shear force sensor integrated into the braking device of FIG. 2, where the second electrode has two extensions;

FIG. 3c shows a section along an xz plane of the shear force sensor from FIGS. 3a and 3b;

FIGS. 4a and 4b show schematically in axonometry and respectively in the drawing a conventional shear force sensor, where the piezoelectric material is electrically polarized along a z-direction of action of the shear force, along which z-direction the parallelepiped piezoelectric material 3 has a longer length;

FIG. 4c shows a section along an xz plane of the shear force sensor from FIGS. 4a and 4b;

FIGS. 5 and 6 show a finite element model simulation of the response of a brake pad incorporating the shear force sensor of the invention illustrated in FIGS. 3a and 3b, respectively, and the same pad but incorporating a conventional shear force sensor such as the one illustrated in FIGS. 4a and 4b;

FIG. 7 shows an axonometric view of a second mode of implementation of the piezoelectric shear force sensor according to the invention involving a single extension of the second electrode;

FIG. 8 shows an experimental test performed on a dynamometer where dynamic braking is reproduced involving the application of a combined normal force and shear force on a conventional reported electrode force sensor (WAC) integrated into the two brake pads;

FIG. 9 shows an experimental test performed on a calibration machine that applies a pure shear force to a conventional reported electrode force sensor (WAC) embedded in the two pads of a brake;

FIG. 10 shows a finite element model evaluating the effect of a combination of normal and shear forces on a conventional reported electrode force sensor (WAC) attached to a metal plate, constrained at the edges and free to deform.

### DETAILED DESCRIPTION

The following detailed description refers to the attached drawings, which are a part of the same. In the drawings, similar reference numbers identify typically similar components, unless the context indicates otherwise. The forms of illustrative implementation described in the detailed description and in the drawings are not understood to be limitative. Other forms of implementation may be used, and other changes may be made without deviating from the spirit or scope of the subject presented here. The aspects of this disclosure, as generally described in this context, and illustrated in the figures, may be ordered, replaced, combined, and designed in a wide variety of different configurations, all of which are explicitly contemplated and are part of this description.

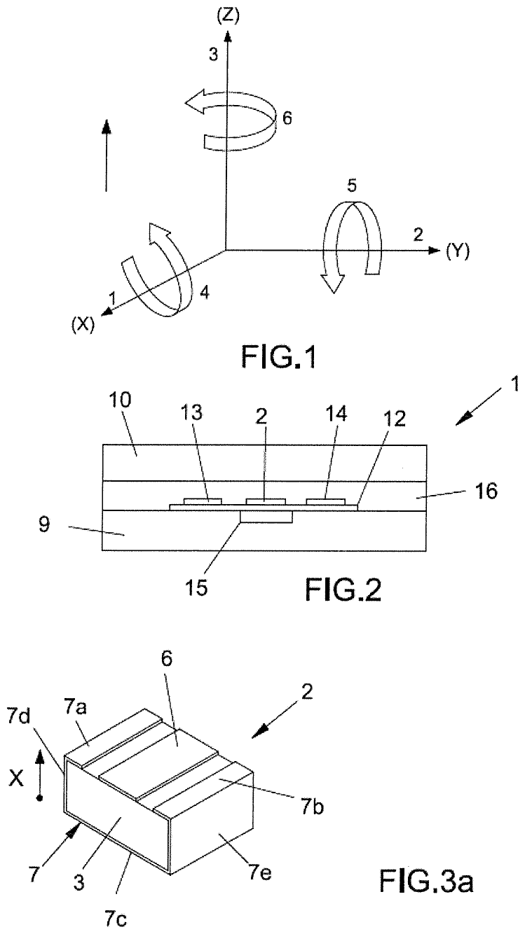

With reference to FIGS. 1-3c and 7, the sensorized shear force detecting braking device 1 includes a piezoelectric shear force sensor 2 comprising a piezoelectric material 3, e.g., a sheet of piezoelectric material 3, having a first flat main face 4 and a second flat main face 5 facing the first flat main face 4.

The first main flat face 4 and the second main flat face 5 extend in parallel planes identified by two orthogonal directions y and z.

The piezoelectric material 3 is electrically polarized, with an electric vector field E, in the z direction which also identifies shear stress direction S of the piezoelectric material 3.

As shown, the z-direction is the direction along which the parallelepiped piezoelectric material 3 has the longest length.

On the first main face 4 of the piezoelectric material 3, at least one first reading electrode 6 is placed, in particular the first reading electrode 6 being entirely placed on the first main face 4 of the piezoelectric material 3.

On the second main face 5 of the piezoelectric material 3, at least one first reading electrode 7 is placed.

The electrical signal is collected by readout electrodes 6, 7 when, in a braking event, the piezoelectric material 3 is simultaneously subjected to a normal force in an x direction orthogonal to the two y and z directions and to the shear force in the z direction.

Advantageously, the second electrode 7 has at least one extension 7a, 7b separated from the first electrode 6 and arranged symmetrically with respect to the y- and z-axes.

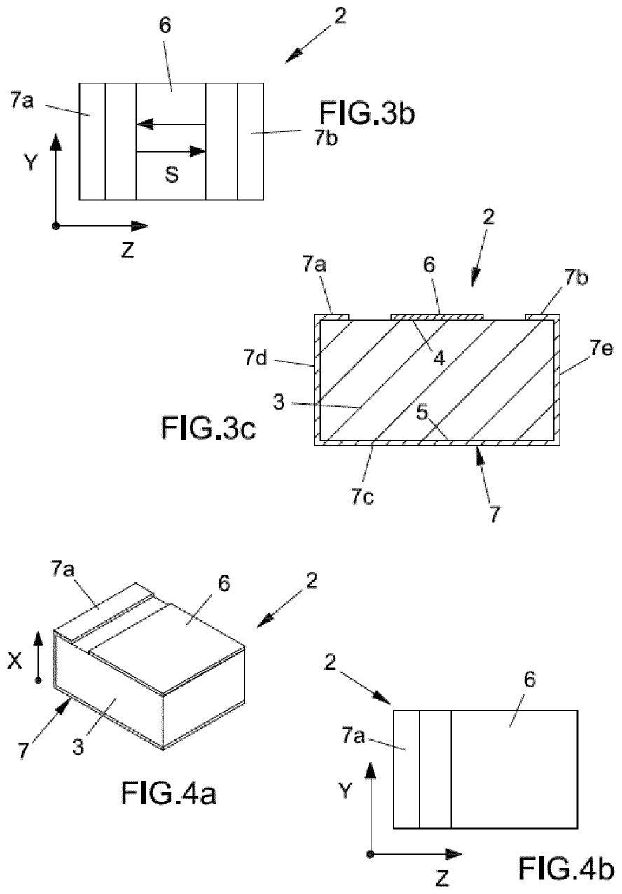

The force sensor 2 illustrated in FIGS. 3a-3c involves two extensions 7a, 7b while the force sensor 2 illustrated in FIG. 7 involves a single extension 7a. However, there can also be more than two extensions of the second electrode 7.

Preferably, the piezoelectric material 3 has a quadrangular configuration.

In practice, with reference to the solution illustrated in FIGS. 3a-3c, the second readout electrode 7 includes a first section 7c placed on the second flat face 5 of the piezoelectric material 3, a second and third opposing sections 7d, 7e folded from the first section 7c and placed along opposite perimeter edges of the piezoelectric material 3, a fourth and fifth opposite sections folded from the second and third opposite sections 7d, 7e and placed along the first face 4 of the piezoelectric material 3 to define opposite extensions 7a, 7b.

The two extensions 7a, 7b of the second readout electrode 7 extend along the opposite edges of the piezoelectric material 3.

Conversely, with reference to the solution illustrated in FIG. 7, the second readout electrode 7 includes a first section placed on the second flat face 5 of the piezoelectric material 3, second, third, fourth and fifth contiguous sections folded from the first section and placed along opposite perimeter edges of the piezoelectric material 3, a sixth, seventh, eighth, and ninth contiguous sections folded from the second, third, fourth, and fifth sections and placed along the first face 4 of the piezoelectric material 3 to define extension 7a.

A non-illustrated variant of the force sensor 2, again where piezoelectric material 3 has a quadrangular configuration, involves four separate extensions of the second readout electrode 7 that converge from the four sides of the piezoelectric material 3 toward the center of the first face 4 of the friction material 3 where the first readout electrode 6 is placed.

The first electrode 6 is also symmetrically placed with respect to said axes y and z.

The piezoceramic material 3 can be made up of a screen printed layer or a discrete element.

The piezoelectric material may include synthesized polycrystalline ferroelectric ceramic material such as barium titanate (BaTiO3) and lead zirconate titanate (PZT).

The piezoelectric material in this disclosure is not limited to synthesized ceramics, and may include other types of ferroelectric material.

Each readout electrode 6, 7 may also be formed of a layer deposited by screen printing or sputtering on the piezoelectric material 3.

In some forms of implementation, the readout electrodes 6, 7 may be formed by a screen printed layer of metallic material, such as silver, gold, copper, nickel, or palladium. In one form of implementation, the readout electrodes 6, 7 may be formed by ink or silver paste.

In some forms of implementation, one or more of the readout electrodes 6, 7 may be partially or completely covered by a protective material, such as a layer of insulation glass or ceramic, to electrically and thermally insulate the electrodes and prevent oxidation.

In other solutions, the readout electrodes are also discrete elements.

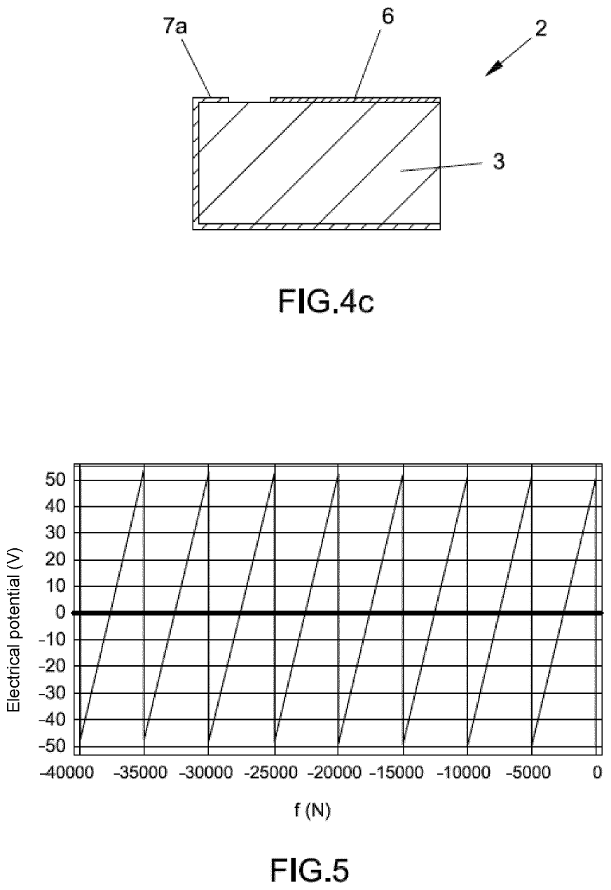

In FIGS. 4a-4c, the parts of the conventional shear force sensor equivalent to the shear force sensor of this invention are illustrated using the same numerical reference.

It can be seen that the main difference is the lack of the second electrode extension 7 and the asymmetrical arrangement of the two electrodes 6 and 7 with respect to the y and z axes.

With reference once again to the invention, the sensorized braking device 1 may include a smart brake pad.

A smart brake pad is a sensorized brake pad configured (e.g., with adequate architecture of the hardware and software system and some algorithms) to measure one or more parameters, such as the temperature of the brake pad and/or static and dynamic quantities, including normal forces and shear applied during braking.

The brake pad includes a backing plate 9, a block of friction material 10, and an electrical circuit 12 with at least one shear sensor 2 as described in this disclosure and preferably also at least one other sensor 13, 14 for example a normal force sensor and/or a temperature sensor. Normal force sensors may include piezoceramic sensors, but alternatively may also be capacitive or piezoresistive sensors.

Temperature sensors can be thermistors, for example PT1000, PT200 or PT100.

The electrical circuit 12 has electrical terminals arranged in a region 15 to collect signals from the brake pad.

The backing plate 9, preferably but not necessarily consisting of a metal, directly supports the electrical circuit 12.

The friction material block 10 is applied to the side of the backing plate 9 where the electrical circuit 12 is located, the electrical circuit 12 is therefore embedded between the backing plate 9 and the friction material block 10.

In some forms of implementation, as illustrated, the brake pad also includes a damping layer 16 that encompasses the sensors 2, 13, 14 and is interposed between the electrical circuit 12 and the block of friction material 10.

The smart braking device may include a limited number of sensors in order to limit the number of operations and the electronic power budget so as to be suitable for a wireless system for on-board application.

During use, the brake pad may be capable of transmitting an electric signal proportional to the braking forces applied to the brake pad as a consequence of contact with the element that is braked, e.g., a disc from braking device 1.

The shear sensor may preferably have at least 0.2 mm thickness of the piezoelectric material sheet with an operating temperature higher than 200° C.

In various forms of implementation, the shear force sensor allows measurement of wear, residual resistance and/or braking torque.

The electrical circuit 12 on which the sensors 2, 13, 14 are installed is electrically insulated. The electrical circuit 12 has appropriately shaped branches for placing the sensors 2, 13, 14 in distinct locations on the backing plate 12.

The electrical circuit 12 may be a screen printed circuit.

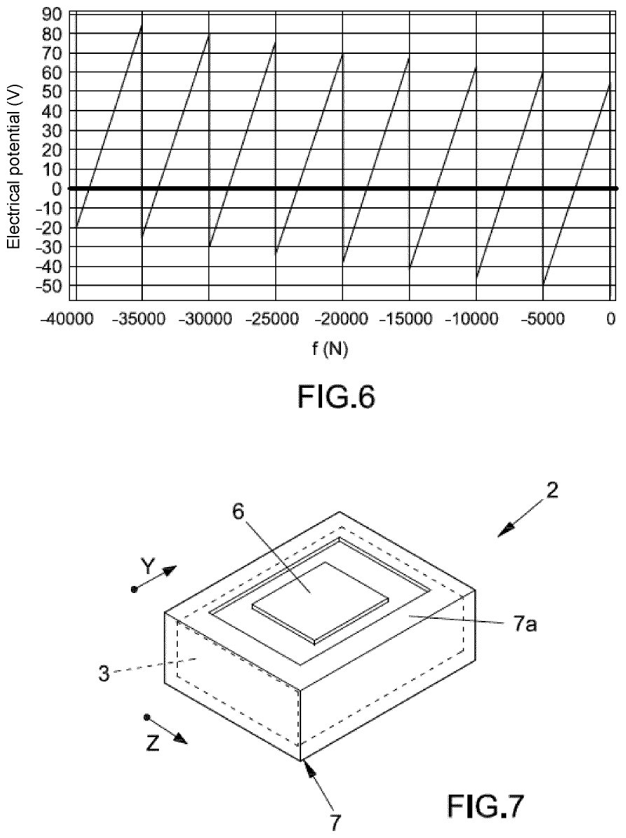

We now refer to FIGS. 5 and 6.

The simulation provides an electrical potential (V), represented on the ordinate, read from the electrodes as a compressive force or normal force f (N), represented on the abscissa, for two shear forces having the same modulus but opposite sign.

The readings are represented by the cusp points in the positive ordinate quadrant for the shear force of one sign, and the cusp points in the negative ordinate quadrant for the shear force of the opposite sign.

The two shear forces of opposite sign simulate the two brake pad shear forces acting on opposite sides of the brake disc.

The result is surprising in that the brake pad with a conventional shear force sensor (FIG. 6) shows a marked dependence of the reading on the intensity of the nominal force f (N) (the cusp points are at progressively decreasing elevations), while the brake pad with a shear force sensor according to the invention (FIG. 5) shows a reading that is substantially independent of the intensity of the nominal force f (N) (the cusp points in each quadrant are at nearly constant elevations).

In practice with the shear force sensor according to the invention, since the deformation of the shear force sensor is symmetrical with respect to the direction of the y- and z-axes, the second electrode 7 is capable of performing symmetrical charge collection at opposite edges of the piezoelectric material 3 from which the two extensions 7a and 7b depart.

Edge effects, on the other hand, appear to affect the operation of the conventional shear force sensor shown in FIGS. 4a-4c, thereby producing an asymmetric response.

In support of the invention, experimental tests performed on conventional WAC force sensors where the reported electrode is not arranged symmetrically with respect to the y and z axes are provided below.

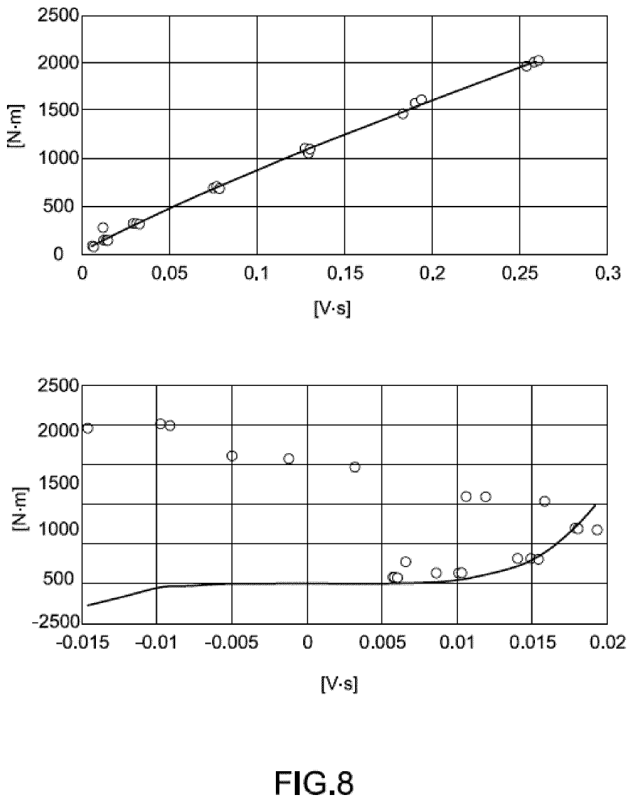

FIG. 8 clearly shows the interference of “crosstalk” which gives a positive contribution in one case (brake pad associated with the upper graph) and a negative one in the other case (brake pad associated with the lower graph), which makes a conventional reported electrode sensor unusable for the desired application.

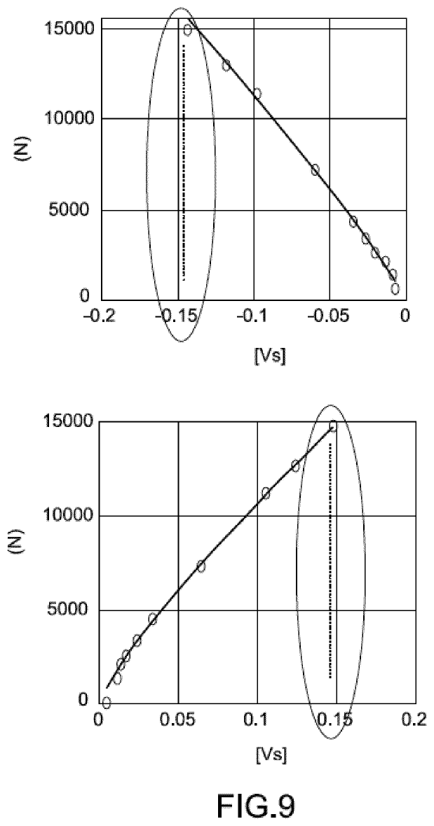

FIG. 9 shows that the two brake pads (one associated with the upper graph and one with the lower graph) give a symmetrical signal only if a pure shear force is applied, which confirms that a conventional reported electrode sensor cannot be used for the desired application, which necessarily involves the coexistence of a normal force and a shear force during dynamic braking.

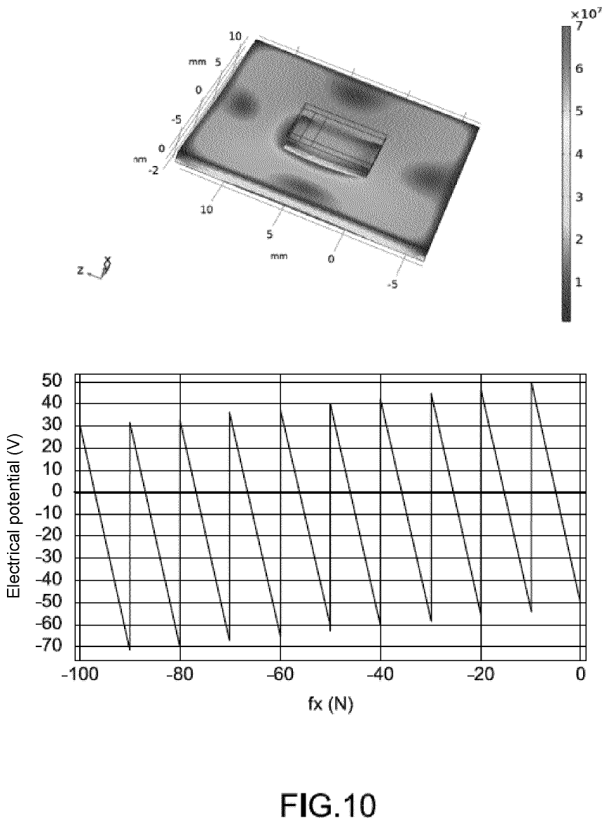

In FIG. 10, the dot plot in the upper quadrant shows the signal detected by the sensor when a positive fixed shear force is applied as the normal force changes (on the abscissa), while the dot plot in the lower quadrant shows the signal detected by the sensor when a negative fixed shear force is applied as the normal force changes (on the abscissa). Once again, we see that the shear force results in a signal that is distorted by the presence of the normal force, since the more intense the normal force, the more asymmetrical the sensor response.

The scope of this disclosure must not be limited by the particular disclosed forms of implementation described above, but must be determined only by a proper reading of the following claims as well as their full scope of equivalents.

1. Sensorized braking device for a vehicle, comprising:
at least one piezoelectric shear force sensor; and
an electrical circuit configured to collect signals from at least one sensor;
wherein said sensor comprises: a piezoelectric material, a first and at least a second readout electrode, wherein said piezoelectric material comprises a first flat face and a second flat face facing said first flat face, the first and second flat faces extending in parallel planes identified by two orthogonal directions y and z, wherein said piezoelectric material is polarized in said z direction,
wherein an electrical signal can be collected by said readout electrodes when said piezoelectric material is simultaneously subjected to a normal force in a direction x orthogonal to said two directions y and z and to said shear force in said z direction; and
wherein said first electrode is positioned on the first face and said second electrode is positioned on the second face and has at least one extension on the first face separated from said first electrode, and in that at least one extension of said second electrode is arranged symmetrically with respect to said y- and z-axes.

2. The sensorized braking device for a vehicle according to claim 1, characterized in that said first electrode is entirely positioned on the first face.

3. The sensorized braking device for a vehicle according to claim 1, characterized in that it comprises a brake pad comprising a backing plate and a block of friction material, wherein said electrical circuit is interposed between said backing plate and said block of friction material and said at least one sensor is interposed between said electrical circuit and said block of friction material.

4. The sensorized braking device for a vehicle according to claim 1, wherein said piezoelectric material is piezoceramic.

5. A piezoelectric shear force detection sensor, comprising:
a piezoelectric material; and
a first and at least a second readout electrode;
wherein said piezoelectric material comprises a first flat face and a second flat face facing said first flat face, the first and second flat faces extending in parallel planes identified by two orthogonal directions y and z,
wherein said piezoelectric material is polarized in said z direction,
wherein an electrical signal can be collected by said readout electrodes when said piezoelectric material is simultaneously subjected to a normal force in a direction x orthogonal to said two directions y and z and to said shear force in said z direction; and
wherein said first electrode is positioned on the first face and said second electrode is positioned on the second face and has at least one extension on the first face separated from said first electrode, and in that at least one extension of said second electrode is arranged symmetrically with respect to said y- and z-axes.

6. The Piezoelectric shear force detecting sensor according to claim 5, wherein said first electrode is positioned symmetrically with respect to said y- and z-axes.

7. The piezoelectric shear force detecting sensor according to claim 5 wherein said piezoelectric material has a quadrangular configuration and said at least one extension comprises an extension extending along all edges of said piezoelectric material.

8. The piezoelectric shear force detecting sensor according to any claim 5 wherein said piezoelectric material has a quadrangular configuration and said at least one extension comprises two extensions extending along the opposite edges of said piezoelectric material.

9. A piezoelectric shear force detecting method with a sensorized braking device for a vehicle, the method comprising:
at least one piezoelectric shear force detecting sensor; and
an electrical circuit configured to collect signals from at least one sensor;
wherein said sensor comprises: a piezoelectric material, a first and at least a second readout electrode,
wherein said piezoelectric material comprises a first flat face and a second flat face facing said first flat face, said first and second flat faces extending in parallel planes identified by two orthogonal directions y and z,
wherein said piezoelectric material is polarized in said z direction, wherein said first electrode is positioned on said first face and said second electrode is positioned on said second face, and
wherein said second electrode extends on said first face with at least one extension separated from said first electrode, in that at least one extension of said second electrode is disposed symmetrically with respect to said y- and z-axes, and in that an electrical signal is picked up by said reading electrodes when said piezoelectric material is simultaneously subjected to a normal force in a direction x orthogonal to said two directions y and z and to said shear force in said z direction.
